(19) United States
(12) Patent Application Publication
(10) Pub. No.: US 2016/0005680 A1
(43) Pub. Date: Jan. 7, 2016

(54) Exposed-Heatsink Quad Flat No-Leads (QFN) Package

(71) Applicant: NXP B.V., Eindhoven (NL)

(72) Inventors: Emil Casey Israel, Nijmegen (NL); Leonardus Antonius Elisabeth van Gemert, NIijmegen (NL); Tonny Kamphuis, Nlijmegen (NL)

(21) Appl. No.: 14/322,553

(22) Filed: Jul. 2, 2014

(51) Int. Cl. H01L 23/495; H01L 21/82; H01L 21/52

(52) U.S. Cl. CPC H01L 23/49568; H01L 21/52; H01L 21/82

(57) ABSTRACT

Consistent with an example embodiment, there is a method for preparing an integrated circuit (IC) device having enhanced heat dissipation. The method comprises providing a heat sink array having a top-side surface and an under-side surface; the heat sink array has die placement areas on the top-side surface. A plurality of active device die are die bonded onto the die placement areas on the heat sink array. The plurality of active device die are singulated into an individual heat sink device die having a heat sink portion attached to its underside.

### FIELD

This disclosure relates to integrated circuit (IC) packaging. More particularly, this disclosure relates to QFN or other exposed-pad non-leaded packaging, having an exposed heat sink upon which a device die is affixed.

### BACKGROUND

The electronics industry continues to rely upon advances in semiconductor technologies to realize higher-function devices in more compact areas. For many applications realizing higher-functioning devices requires integrating a large number of electronic devices into a single silicon wafer. As the number of devices per given area of the silicon wafer increases, the manufacturing process becomes more difficult.

Many varieties of semiconductor devices have been manufactured having various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

Having manufactured a number of electronic devices on a wafer substrate, a particular challenge is to package these devices for their given purpose. As the complexity of portable systems increases, there is a commensurate need to reduce the size of the individual components which make up the system; the system often is laid out on a printed circuit substrate. One way to reduce the size of individual components is through techniques that reduce the size of packages which contain these devices. A package, often used, is the QFN (quad flat no-leads) package to reduce the vertical profile of the devices attached to the system printed circuit substrate. However, some applications may require the QFN device handle sufficient power that may thermally stress the device die and packaging. Consequently, a heat sink is required to dissipate any excess heat; yet, the heat sink cannot add appreciably to the vertical profile. There is a need for a QFN or similar package that can accommodate a device die with a heat sink with an acceptable profile.

### SUMMARY

The present disclosure addresses the challenge of making a QFN semiconductor having a lower vertical profile with enhanced thermal performance. A plurality of device die are attached to a heat sink array. The plurality of device die are singulated into individual devices attached to a heat sink portion. These individual device die/heat sink assemblies are placed on a carrier tape along with a lead frame array. The device die are wire bonded to the lead frame array. The assemblies are encapsulated in a molding compound. The molded assemblies are singulated into individual devices. The devices have exposed electrical contacts and heat sink on its underside. The exposed heat sink provides enhanced thermal coupling from the device to the printed circuit board (PCB) to which it is mounted.

In addition, the present disclosure addresses a long-felt need to decouple the die-bonding conditions from their detrimental effects on lead frame and/or carrier. For high-temperature die-bonding, these effects can include oxidation of the lead frame surface, causing problems with mold adhesion or wire bonding, or adhesive decomposition in the case of a tape-based carrier.

Furthermore, the exposed heat sink underside provides for a high-integrity electrical connection between the device die and printed circuit board (PCB) to which it is soldered.

In an example embodiment, there is a method for preparing an integrated circuit (IC) device having enhanced heat dissipation. The method comprises providing a heat sink array having a top-side surface and an under-side surface, the heat sink array having die placement areas on the top-side surface, die bonding a plurality of active device die onto the die placement areas on the heat sink array, and singulating the plurality of active device die into an individual heat sink device die having a heat sink portion attached to its underside.

In an example embodiment, there is a method for preparing an integrated circuit (IC) device having enhanced heat dissipation. The method comprises, providing a heat sink array having a top-side surface and an under-side surface, the heat sink array having die placement areas on the top-side surface, the heat sink array having notches on the under-side surface, the notches defining a separation among one another of the die placement areas. A plurality of active device die are die bonded, with a die attach material, onto the die placement areas on the heat sink array, the die bonding is at a predetermined elevated-temperature. The plurality of active device are singulated into an individual heat sink device die having a heat sink portion attached to its underside, the heat sink array being singulated about the middle of the notches. The method further provides a lead frame with bond pad landings, the bond pad landings having upper surfaces and opposite lower surfaces, the bond pad landings surrounding a die placement area. The lead frame is mounted, on the lower surface, onto an adhesive carrier tape. In the die placement area, the heat sink device die is placed, with its under-side surface onto the adhesive carrier tape. The heat sink device die is conductively bonded to the bond pad landings. The conductively bonded heat sink device die and lead frame are encapsulated in a molding compound. Removing the adhesive carrier tape, exposes the under-side surface of the heat sink device die and the opposite lower surfaces of the bond pads.

In an example embodiment, there is an integrated circuit (IC) having enhanced heat dissipation. The IC comprises an active device die of having a top-side surface and an under-side surface. A bondable die-attach layer is on the under-side surface of the active device die. A heat sink assembly has a top-surface and an opposite under-side surface to accommodate the active device die, and wherein the active device die is bonded to the top-side surface of the heat sink assembly via the bondable die-attach layer.

The above summaries of the present invention are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1 is a flow diagram of an example assembly process in accordance with the present disclosure;

FIGS. 2A-2F are side views of an exposed heat sink QFN package assembled in accordance with the present disclosure; and

FIGS. 3A-3B is a side view and a top view of an exposed heat sink QFN package assembled in accordance with the present disclosure, showing example dimensions

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present disclosure has been found useful in enhancing the heat dissipation characteristics a FET device assembled in a QFN package. These devices may be expected to dissipate about 100 mW to about 5 W, or more.

In an example process the wafers are ground down to about 200 μm to prepare the device die that will ultimately be assembled onto the heat sink. To further reduce vertical profile, in another example process, the back grind thickness may be reduced down to 50 μm, after this process the back side metallization is applied. This metallization is in the order of a few micro-meters. One, or more metallization deposition techniques may be applied or even a combination of them (e.g., initial sputter layer which is increased in thickness by a plating process). The metallization provides for sufficient adhesion of the device die as it is attached to the heat sink.

The present disclosure obviates the need to attach a separate heat sink to the QFN package in that the underside of the package is in direct contact with the PCB; the PCB provides a large area in which heat may be dissipated. Having prepared the underside of the devices, the attaching of the device die to the heat sink portion prior to assembly in a QFN lead frame, provides for better heat spreading that for a device die packaging in a conventional QFN configuration.

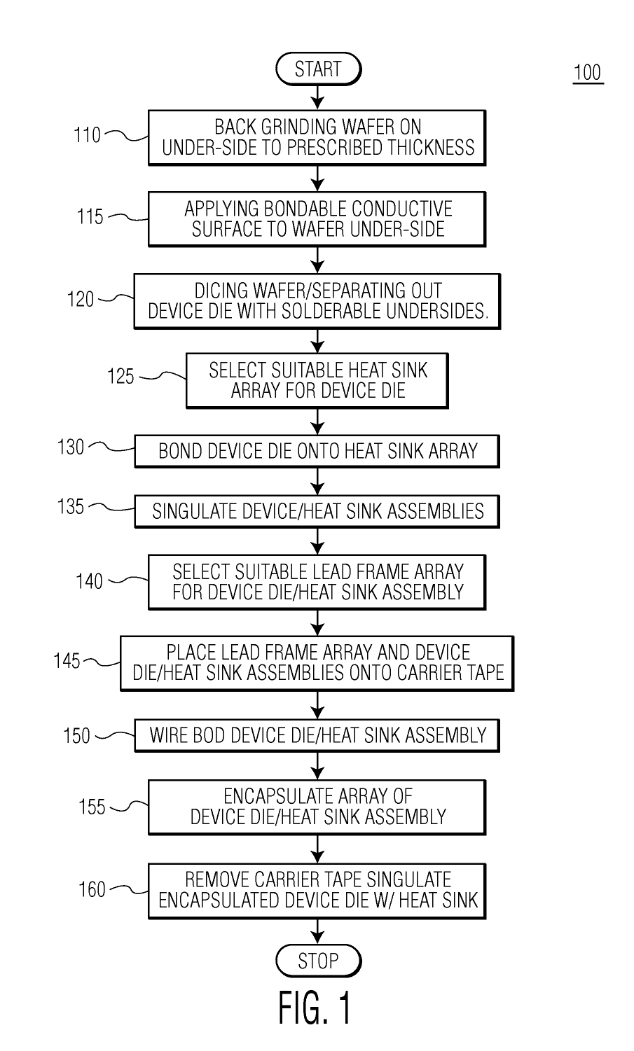

Making reference to FIG. 1, in an example process 100 according to the disclosure, a wafer substrate on its under-side undergoes back-grinding to a prescribed thickness 110. After back-grinding, a suitable bondable conductive surface is applied to the wafer's under-side 115. The bondable conductive surface may be applied with a variety of techniques, which may include, but are not limited to, sputtering, evaporation, chemical vapor deposition, electro-plating, or a combination thereof. Bondable conductive surfaces may include NiAu, Cu, NiAg, or other suitable alloys. Having coated the wafer under-side, the wafer is diced and device die, having bondable under-sides, are separated out 120. Dicing of the wafer may be accomplished with sawing, cleaving, laser ablation or other suitable method.

In another example process, the device die having a bondable underside surfaces may be prepared, in advance, in a separate process or from a third party. The prepared device die are then appropriate for bonding to the heat sink array, as described in the present disclosure.

As determined by the device die type, a heat sink array is prepared 125. Having prepared the heat sink array, device die are bonded in die-attach areas on the heat sink array 130. The device die having solderable undersides may be re-flow soldered onto the die attach areas of the heat sink array 125.

The present disclosure permits the use of high-temperature die-bonding. The lead frame is spared from deleterious effects of the process temperatures, the effects including lead frame oxidation which may result in poor molding compound adhesion or wire-bonding problems. The user may make use of higher-temperature die-attach techniques which may include, but are not necessarily limited to, solder, eutectic, silver (Ag)-sinter, conductive adhesive, etc. For example, Ag-sinter is performed at about 200° C. to about 300° C., Pb-solder at about 350° C., eutectic at about 400° C., conductive adhesive at 150° C. to 250° C.

Further, the high temperatures may not be compatible with use of adhesive carrier tape; the high temperatures degrade the tape.

The heat sink array with attached device die is singulated into individual assemblies 135. For the type of device die/heat sink assembly, a suitable lead frame array is selected 140. Onto carrier tape, the lead frame array along with the device die/heat sink assemblies are placed 145. The device die/heat sink assemblies are surrounded by bond pad areas of the lead frame array. Devices are wire bonded to the bond pad areas on the lead frame array 150. The array of device die/heat sink assemblies and the lead frame array are encapsulated 155.

In another example embodiment, the use of wire bonds may not be appropriate, especially were minimizing interconnect inductance and/or resistance is critical. Ribbon bonding may often be used. For a given application, a wire bond may have a given diameter of about 25.4 μm (0.001 in) and a ribbon bond may have a cross-section of about 25.4 μm×76.2 μm (0.001 in×0.003 in). Interconnect inductance can cause impedance mismatches, ringing, distortion pulses. For high speed circuits, excess inductance results in reduced bandwidth. Because of this need for reduced inductance, ribbon bonding may often specified instead of wire bonding. This is especially true for wide band components where parameters such as group delay must be controlled over a very wide bandwidth. Ribbon bonds may be preferred because a typical ribbon bond has two to three times less inductance than that of a wire bond. The increased cross-sectional area serves to lower the resistance of typical ribbon bonds compared to typical wire bonds, which in turn lowers R_{DSon} in relevant electrical pathways. More detailed information may be found in “Quick Reference Guide: Ribbon Bond vs. Wire Bond.” NATEL Engineering Co., Inc., Chatsworth, Calif., USA, pp.4.

In another example embodiment, a clip bonding technique may be used. Further information may be found in U.S. patent application titled, “Exposed Die Clip Bond Power Package” of Leonardus van Gemert and Emil Israel, Docket No. 81626917US01 (Application No. ##/###,###). This application is incorporated by reference in its entirety.

The device die/heat sink assemblies may be configured as strips, for example, 50 mm×150 mm or 100 mm×300 mm. Die sizes which may be used range from about 1 mm×1 mm to about 10 mm×10 mm. The number of device pins may range from 2 to 50.

After encapsulation, the carrier tape is removed. The assembled array of encapsulated devices is then sawed apart into individual assembled devices whose lead frame contacts are exposed, as well, as the exposed heat sink 160; these exposed contact areas would be coplanar. The heat sink and exposed lead frame contacts would be prepared appropriately so that they have surfaces with a sufficient affinity to solder.

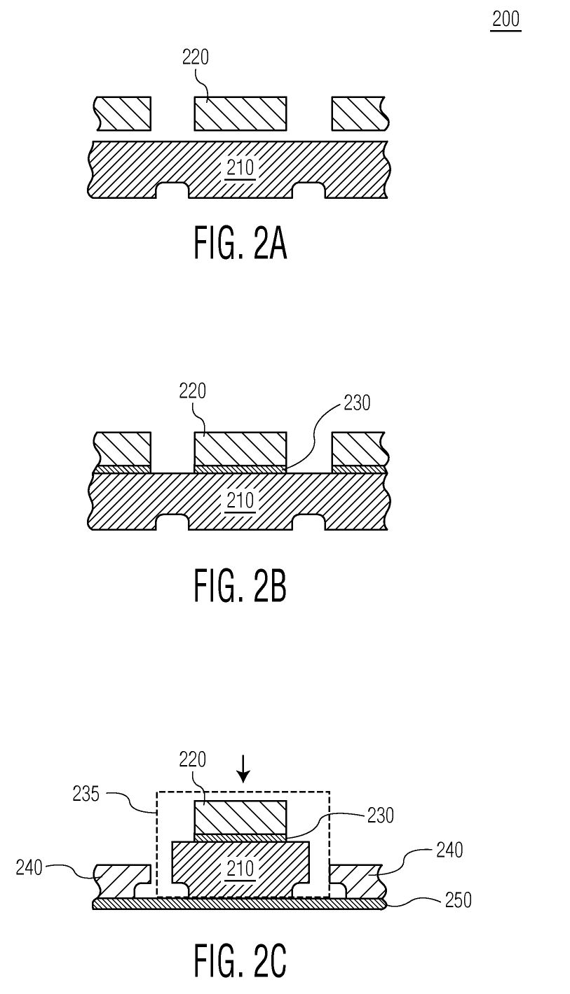

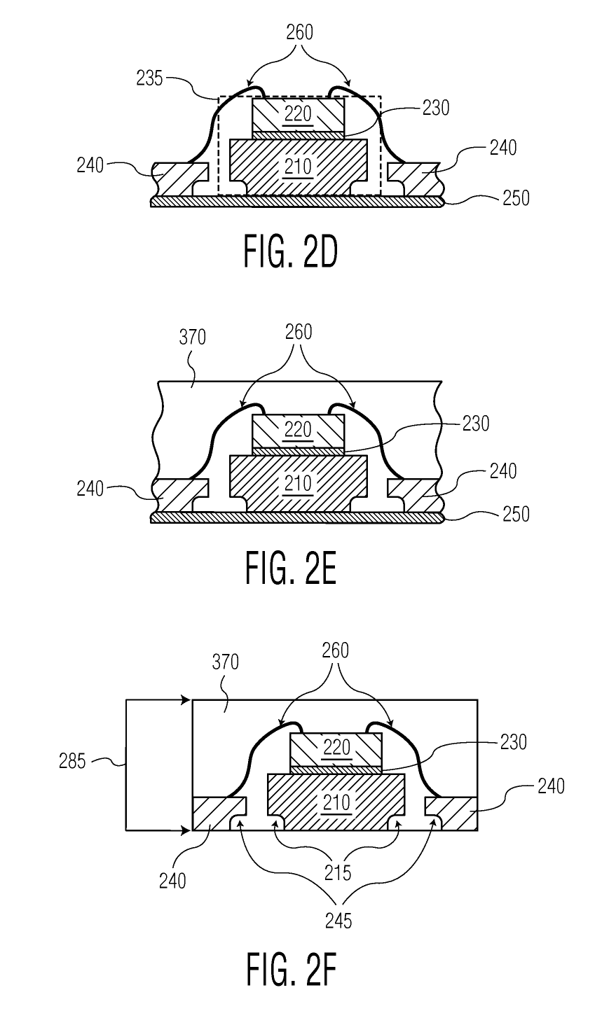

In an example embodiment, as depicted in FIGS. 2A-2F, a series of side views illustrate the assembly of a device die according to the disclosure. FIG. 2A shows heat sink array portion 210 upon which a device die 220 is mounted. FIG. 2B, shows the device die 220 may be soldered or attached with conductive adhesive 230 to the heat sink array portion 210. The device die 220 mounted onto the heat sink array 210 are singulated into individual device/heat sink assemblies 235.

Refer to FIG. 2C. The individual device die/heat sink assemblies 235 (i.e., an individual heat sink device die) are mounted onto carrier tape 250 along with a lead frame assembly 240 (the lead frame assembly having an array of device positions). Both the underside surfaces of the lead frame assembly 240 and device/heat sink assemblies are mounted directed to the carrier tape 250. Refer to FIG. 2D. Bond wires 260 electrically connect active areas of the device die to the lead frame contacts 240.

The mounted and wire bonded device die/heat sink assemblies 235 are encapsulated in a molding compound 270. After molding, the carrier tape 250 is removed (See FIG. 2E). Note that the molding compound 270 has enhanced mechanical anchoring at the overhangs 245 of the lead frame 240 and overhangs 215 on the heat sink 210. Refer to FIG. 2F. The carrier tape 250 is removed and the array of completed devices 280 are singulated into individual devices 285 whose device die 220 are attached to a heat sink 210. The underside surfaces of the lead frame 240 and underside surface of the heat sink 210 facilitate mounting of the device onto a system printed circuit board.

In example processes, carrier ring apparatus may be used. For example, the carrier ring apparatus may be 50 mm'200 mm or 80 mm×300 mm, though other sizes may be available owing to the particular assembly equipment used. If the lead frame is mechanically robust, a carrier ring is not required. Equivalently, a carrier plate of glass, ceramic, or metal can be used.

The number of fabricated devices can range from several hundred to even several thousand pieces. QFN package sizes may range from millimeters on a side down to about 0.5 mm×1 mm. Other leadless (metal-based) packages may include, but are not necessarily limited to, aQFN (advanced quad flat no lead), LLGA (leadless land grid array), TLA (thermal leadless array), EFLGA (electroforming type land grid array), and TLEM (transcription lead of electroforming method), etc. The embodiments in the present disclosure may also be implemented in exposed-pad leaded devices such as HSOP (heat slug outline package), HQFP (heatsink quad flat pack) or other similar package types.

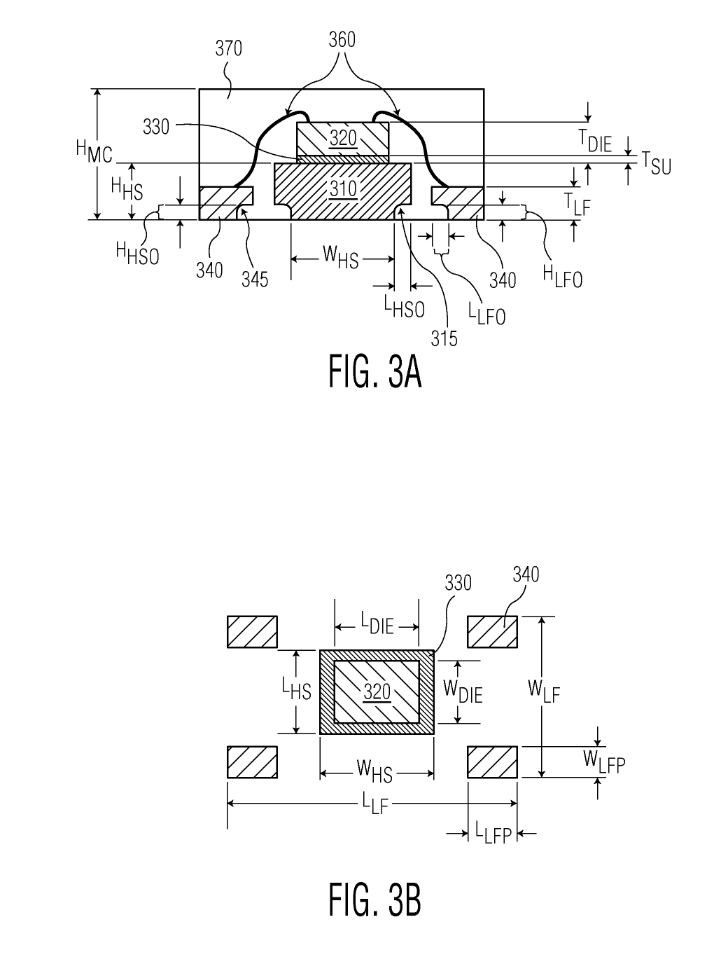

Making reference to FIGS. 3A, in an example embodiment, an assembled device die 320 whose underside has been mounted 330 to a heat sink 310 within a lead frame 340. Overhangs 315 in the heat sink 310 and overhangs 345 in the lead frame enhance the mechanical anchoring of the molding compound 370. The device 320 has wire bonds 360 to electrically connect the device die 320 to the lead frame 340. The FIGS. 3A and 3B indicate dimensions (for an etched lead frame and heat sink) to provide the user with the size and scale of devices which may be assembled according to the disclosed embodiments. In another embodiment, punched lead frames and heat sinks may be used. Or in other embodiments, a combination of etched and punched lead frames and heat sinks may be used. Of course, the specific dimensions for punched lead frames and heat sinks would have a wider range of dimensions than those that are etched.

| Sym- | | Dimensions | | Dimensions | Dimensions | |
|---|---|---|---|---|---|---|
| bol | Meaning | (Small) | | (Medium) | (Large) | FIG. |
| H_{MC} | Height of | 0.5 | mm | 0.8 | 2 | 3A |
| | Device w/ | | | | | |
| | Molding | | | | | |
| | Compound | | | | | |
| H_{HS} | Height of | 0.2 | mm | 0.5 | 1.2 | 3A |
| | Heatsink | | | | | |
| W_{HS} | Width of | 1 | mm | 4 | 8 | 3A |
| | Heatsink | | | | | |
| T_{LF} | Thickness of | 0.1 | mm | 0.2 | 0.4 | 3A |
| | Lead Frame | | | | | |
| T_{Die} | Die Thickness | 0.05 | mm | 0.2 | 0.4 | 3A |
| T_{SU} | Thickness | 0.002 | mm | 0.020 | 0.1 | 3A |
| | Solderable | | | | | |
| | Underside | | | | | |
| H_{HSO} | Height of | 0.1 | mm | 0.25 | 0.6 | 3A |
| | Heatsink | | | | | |
| | Overhang | | | | | |
| H_{LFO} | Height of Lead | 0.05 | mm | 0.1 | 0.2 | 3A |
| | Frame | | | | | |
| | Overhang | | | | | |
| L_{LFO} | Length Lead | 0.05 | mm | 0.1 | 0.2 | 3A |
| | Frame | | | | | |
| | Overhang | | | | | |
| L_{HSO} | Length | 0.1 | mm | 0.2 | 0.4 | 3A |
| | Heatsink | | | | | |
| | Overhang | | | | | |
| L_{Die} | Length of Die | 1 | mm | 4 | 8 | 3B |
| W_{Die} | Width of Die | 1 | mm | 4 | 8 | 3B |
| L_{HS} | Length | 1 | mm | 4 | 8 | 3B |
| | Heatsink | | | | | |
| W_{HS} | Width of | 1 | mm | 4 | 8 | 3B |
| | Heatsink | | | | | |
| L_{LF} | Length of Lead | 1.5 | mm | 5 | 10 | 3B |
| | Frame | | | | | |
| W_{LF} | Width of Lead | 1.5 | mm | 5 | 10 | 3B |
| | Frame | | | | | |
| L_{LFP} | Length of Lead | 0.3 | mm | 0.5 | 1.5 | 3B |
| | Frame Pad | | | | | |
| | Landing | | | | | |
| W_{LFP} | Width of Lead | 0.2 | mm | 0.3 | 1 | 3B |
| | Frame Pad | | | | | |
| | Landing | | | | | |

Having been able to apply higher temperature processing to the die attach process in the die attaching of the device die onto the heat sink portion, a QFN device has been assembled having a greater power dissipation performance and improved reliability. The die attach process occurs separately and thus, QFN lead frame or carrier is spared from the effects of the die attach process.

Various exemplary embodiments are described in reference to specific illustrative examples. The illustrative examples are selected to assist a person of ordinary skill in the art to form a clear understanding of, and to practice the various embodiments. However, the scope of systems, structures and devices that may be constructed to have one or more of the embodiments, and the scope of methods that may be implemented according to one or more of the embodiments, are in no way confined to the specific illustrative examples that have been presented. On the contrary, as will be readily recognized by persons of ordinary skill in the relevant arts based on this description, many other configurations, arrangements, and methods according to the various embodiments may be implemented.

To the extent positional designations such as top, bottom, upper, lower have been used in describing this disclosure, it will be appreciated that those designations are given with reference to the corresponding drawings, and that if the orientation of the device changes during manufacturing or operation, other positional relationships may apply instead. As described above, those positional relationships are described for clarity, not limitation.

The present disclosure has been described with respect to particular embodiments and with reference to certain drawings, but the invention is not limited thereto, but rather, is set forth only by the claims. The drawings described are only schematic and are non-limiting. In the drawings, for illustrative purposes, the size of various elements may be exaggerated and not drawn to a particular scale. It is intended that this disclosure encompasses inconsequential variations in the relevant tolerances and properties of components and modes of operation thereof. Imperfect practice of the invention is intended to be covered.

Where the term “comprising” is used in the present description and claims, it does not exclude other elements or steps. Where an indefinite or definite article is used when referring to a singular noun, e.g. “a” “an” or “the”, this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Numerous other embodiments of the disclosure will be apparent to persons skilled in the art without departing from the spirit and scope of the disclosure as defined in the appended claims.

1. A method for preparing an integrated circuit (IC) device having enhanced heat dissipation, the method comprising:
providing a heat sink array having a top-side surface and an under-side surface, the heat sink array having die placement areas on the top-side surface;
die bonding a plurality of active device die onto the die placement areas on the heat sink array;
singulating the plurality of active device die into an individual heat sink device die having a heat sink portion attached to its underside.

2. The method as recited in claim 1, wherein the heat sink array has notches on the under-side surface, the notches defining a separation among one another of the die placement areas.

3. The method as recited in claim 1, wherein during the singulating of the plurality of active device die, the heat sink array is sawed apart about the middle of the notches.

4. The method as recited in claim 1, wherein die bonding is an elevated-temperature process selected from at least one of the following: solder, eutectic, Ag-sinter, conductive adhesive.

5. The method as recited in claim 2, further comprising:
providing a lead frame with bond pad landings, the bond pad landings having upper surfaces and opposite lower surfaces, the bond bad landings situated about a die placement area on one or multiple sides;
mounting the lead frame, on the lower surface, onto an adhesive carrier tape;
in the die placement area, placing the heat sink device die, with its under-side surface onto the adhesive carrier tape;
conductively bonding the heat sink device die to the bond pad landings; and
encapsulating the wire bonded heat sink device die and lead frame in a molding compound; and
removing the adhesive carrier tape, thereby exposing the under-side surface of the heat sink device die and the opposite lower surfaces of the bond pads.

6. The method as recited in claim 5, wherein bond bad landings surround the die placement area on the lead frame.

7. The method as recited in claim 5, wherein conductively bonding the heat sink die to the pad landings includes at least one of the following: wire bonding, ribbon bonding, clip bonding.

8. The method as recited in claim 5, wherein the lead frame is selected from one of the following package types: QFN, aQFN, LLGA, TLA, EFLGA, TLEM, HSOP, HQFP.

9. A method for preparing an integrated circuit (IC) device having enhanced heat dissipation, the method comprising:
providing a heat sink array having a top-side surface and an under-side surface, the heat sink array having die placement areas on the top-side surface, the heat sink array having notches on the under-side surface, the notches defining a separation among one another of the die placement areas;
die bonding a plurality of active device die, with a die attach material, onto the die placement areas on the heat sink array, the die bonding is at a predetermined elevated-temperature;
singulating the plurality of active device die into an individual heat sink device die having a heat sink portion attached to its underside, the heat sink array being singulated about the middle of the notches;
providing a lead frame with bond pad landings, the bond pad landings having upper surfaces and opposite lower surfaces, the bond pad landings surrounding a die placement area;
mounting the lead frame, on the lower surface, onto an adhesive carrier tape;
in the die placement area, placing the heat sink device die, with its under-side surface onto the adhesive carrier tape;
conductively bonding the heat sink device die to the bond pad landings; and
encapsulating the conductively bonded heat sink device die and lead frame in a molding compound; and
removing the adhesive carrier tape, thereby exposing the under-side surface of the heat sink device die and the opposite lower surfaces of the bond pads.

10. The method as recited in claim 9, wherein conductively bonding the heat sink die to the pad landings includes at least one of the following: wire bonding, ribbon bonding, clip bonding.

11. The method as recited in claim 9, wherein the pre-determined elevated temperature is in the range of about 150° C. to about 400° C.; and
wherein the die attach material consists of one of the following: solder, eutectic, Ag-sinter, conductive adhesive.

12. An integrated circuit (IC) having enhanced heat dissipation, the IC comprising:
an active device die having a top-side surface and an under-side surface;
a bondable die-attach layer on the under-side surface of the active device die; and
a heat sink assembly having a top-surface and an opposite under-side surface to accommodate the active device die, and wherein the active device die is bonded to the top-side surface of the heat sink assembly via the bondable die-attach layer.

13. The IC as recited in claim 12, further comprising, a lead frame having a top-side surface and an opposite under-side surface, the lead frame having pad landings surrounding the active device and heat sink assembly, wherein conductive bonds connect active device die bond pads to the pad landings on the lead frame;
an encapsulant enveloping the active device die, heat sink assembly, and lead frame, wherein the underside surface of the lead frame and the under-side surface of the heat sink assembly are exposed and are coplanar.

14. The IC as recited in claim 13, wherein conductive bonds include at least one of the following: wire bonds, ribbon bonds, clip bonds.

15. The IC as recited in claim 13, wherein the heat sink and lead frame have overhangs that anchor the encapsulant.

16. The IC as recited in claim 13,
wherein the lead frame is etched or punched; and
wherein the heat sink is etched or punched.
